(19) United States
(12) Patent Application Publication
(10) Pub. No.: US 2008/0188037 A1
(43) Pub. Date: Aug. 7, 2008

(54) Method of manufacturing semiconductor chip assembly with sacrificial metal-based core carrier

(75) Inventor: Charles W.C. Lin, Yunghe (TW)

Correspondence Address: TROXELL LAW OFFICE PLLC, 5205 LEESBURG PIKE, SUITE 1404, FALLS CHURCH, VA, 22041, US

(73) Assignee: Bridge Semiconductor Corporation, Taipei (TW)

(21) Appl. No.: 11/984,263

(22) Filed: Nov. 15, 2007

Related U.S. Application Data
(60) Provisional application No. 60/899,573, filed on Feb. 5, 2007.

(51) Int. Cl. H01L 21/00

(52) U.S. Cl. 438/108; 257/E21.001

(57) ABSTRACT

A method of making a semiconductor chip assembly is disclosed. The semiconductor chip assembly is made by attaching a semiconductor chip to a multi-layer build-up substrate with a metal-based core carrier. The build-up substrate layers provide routing functions while the metal-based core carrier provides critical mechanical support for the semiconductor assembly. The metal-based core carrier is sacrificial and is eventually removed with the build-up substrate remaining.

### FIELD OF THE INVENTION

The present invention relates to a semiconductor chip assembly technology; more particularly, relates to assembling an integrated circuit chip on a build-up substrate with a metal-based core carrier.

### DESCRIPTION OF THE RELATED ARTS

Increased integrated circuit (IC) functionality, coupled with the challenges to achieve desired signal integrity and smaller form-factor has birthed a wide range of advanced packaging innovations including flip chip (FC) and chip-scale packaging (CSP). These technologies allow chip to be packed in a very dense area by using a high density interconnect (HDI) substrate to distribute I/O signals effectively from the IC to the board. The HDI substrate not only miniaturizes the foot print of a package, but also improves signal integrity, such as noise reduction, EMI radiation reduction, and low attenuation. A number of new processes have been evolved to provide HDIs and one of t he most popular is a group referred to as sequential build-up substrate (SBU).

Conventional build-up substrates consist of two distinct elements: build-up layers and a core substrate. The process typically begins with a traditional core substrate, such as traditional printed circuit board (PCB). This core substrate serves as the carrier for fabricating the build-up layers and provides major mechanical support. The build-up layers consisting of dielectric layers and wiring layers are sequentially stacked up alternately on both surfaces of the core substrate. The wiring layers consist of a plurality of circuitry patterns that aim to provide various wiring functions. Interlayer connection is provided by laser formed or photo defined conductive vias. In order to interconnect the front-and-back sides of the build-up layers, through holes in the core are typically mechanical drilled or punched and the base circuitry is etched using standard PCB techniques.

FIG. 1 is a cross sectional view of a conventional build-up substrate wherein the build-up layers are formed on both sides of the core substrate. The build-up substrate 110 has a core substrate 120 that is typically made of a glass-epoxy resin. First build-up layers 130 are formed on the core substrate first surface 120a, and second build-up layers 150 are formed on the core substrate second surface 120b. A plurality of through holes 121 is formed to extend through the first surface 120a and the second surface 120b of the core substrate 120. Each of the through holes 121 has a plated conductor 122 formed therein and is filed with a resin 123.

A first build-up layer 130 consists of a first wiring layer 131 formed on the core substrate first surface 120a and portions of the first wiring layer 131 is connected to the first end of the plated conductor 122. A first dielectric layer 132 made of an epoxy resin is coated on the core substrate first surface 120a covering the wiring layer 131 and the filler resin 123 in the first direction. A plurality of first level via holes 133 is formed in the first dielectric layer 132 with bottom exposed on the first wiring layer 131. A second wiring layer 134 is formed on the first dielectric layer 132, and a portion of the second wiring layer 134 extends into the first level via hole 133 and contact the first wiring layer 131 in the first direction. A second dielectric layer 135 is coated on the first dielectric layer 132, and covers the second wiring layer 134. A plurality of second level via holes 136 is formed in the second dielectric layer 135 with bottom exposed on the second wiring layer 134. Likewise, a third wiring layer 137 is formed on the second dielectric layer 135 and a portion of the third wiring layer 137 extends into the second level via hole 136 and contacts the second wiring layer 134 in the first direction.

A solder resist layer 138 is coated on the second dielectric layer 135 and covers the third wiring layer 137 in the first direction. A plurality of openings 139 is formed in the solder resist layer 138 with bottom exposed to the third wiring layer 137 and a plurality of contacting pads 140 is deposited in the openings 139 and on the third wiring layer 137.

The wiring layers 131, 134, 137, the dielectric layers 132, 135, the soldering layer 138 and the contacting pads 140 constitute the first build-up layers 130.

Similar to the first build-up layer 130, the second build-up layers 150 consists of a first wiring layer 151 formed on the core substrate second surface 120b and portion s of the first wiring layer 151 is connected to the second end of the plated through hole conductor 122.

The wiring layer 151, 154,157, dielectric layers 152, 155, solder resist layer 158 and terminal pad 160 constitute the second build-up layers.

The core substrate 120, the first build-up layer 130, and the second build-up layer 150 constitute the conventional build-up substrate 110.

While the conventional build-up substrate has tremendous advantages for high performance chips, its technical and reliability limitations are significant. As the wiring density and the through holes dimension of the core are significantly coarser than those in the build-up layers, the core can only provide limited wiring functions for the connection means for the front and back side of the build-up layers. As a result, even though flip chip terminal pitches can be easily accommodated by the wiring capability in the build-up layers, the through-hole in the core actually imposes a severe restriction on the wiring capability of the second build-up layer. In addition, the plated through holes in the core often destroys the integrity of the voltage layer as it increases capacitance loss and electrical noise.

Besides the wiring restriction problem associated with core laminate, the local and global thermal expansion coefficient (CTE) mismatches of the silicon and substrate materials will induce large thermal stress and strain. As a result, a weak solder joint connection between the semiconductor package and the circuit board will incur during next level board assembly.

Among the material-induced reliability issues, reinforced glass-fiber and epoxy materials in the core substrate contributes significantly to these reliability problems and play a critical role in packaging design. Thermal mismatch of these materials also induce serious warping and handling problems and thus greatly affect the package's manufacturing yield.

As such, the manufacturing processes and material lay-up for a semiconductor package should be carefully designed since not only the electrical and thermal performances of the packaging system can be strongly affected, the degradation of the physical mechanical structure of the package can also cause a serious reliability problem and have an adverse impact on the manufacturing yield.

Both electrical and material induced packaging problems can be reduced by proper design of the interconnect substrate structure including material lay-up and composition. For instance, laminate BGA and LGA packages can be designed to become a core-less BGA packages to minimize the influence from core material and improve electrical performance.

U.S. Pat. No. 7,060,604 describes a core less build-up substrate, in which the use of a laminate board for a core is abandoned. The wiring sheets having fine front-to-back conductive passages are sequentially stacked one another. As such, the problem of restriction on density due to the core structure has been successfully solved.

However, such core-less substrate suffers a serious problem in losing the rigidity support that packaging processes normally require. Furthermore, the deformation of sheets and poor co-planarity control of such ultra-thin substrate would cause dimension and alignment issues during chip assembly, as such, low manufacturing yield and many reliability-related problems would make this approach un-favorable.

Thermally mismatched induced solder joint stress of the package can also be reduced by proper design of the mechanical structure. For instance, BGA and LGA packages can be re-designed to become a PGA package with pin-type contact terminals that extend above the package and act as a stand-off or spacer between the package and the PCB in order to absorb thermal stress and reduce solder joint fatigue. As such, the pillar can be flexed to follow expansion of the two ends, and hence a reduction in the shear stress can be achieved.

Conventional approaches for forming the pillar include a bonded interconnect process (BIP) and a plating process using a photoresist.

BIP forms a gold ball on a pad of the chip and a gold pin extending upwardly from the gold ball using a thermo compression wire bonder. Thereafter, the gold pin is brought in contact with a molten solder bump on a support circuit, and the solder is reflowed and cooled to form a solder joint around the gold pin. A drawback to this approach is that, when the wire bonder forms the gold ball on the pad, it applies substantial pressure to the pad that might destroy an active circuitry beneath the pad. In addition, gold from the pin can be dissolved into the solder to form a gold-tin intermetallic compound which mechanically weakens the pin and therefore reduces reliability.

U.S. Pat. No. 6,177,636, entitled “Connection Components with Posts” issued on Jan. 23, 2001 to Joseph C. Fjelstad disclosed a method of fabricating an interconnection component for a microelectronic device by providing a flexible substrate with plurality of rigid posts serve as the interconnections terminals. These rigid posts are etched from a conductive sheet that is coupled to a supporting structure. After the posts are created, the substrate is then coupled to a semiconductor chip, and bond pads are electrically connected to the respective leads and posts.

While the posts and the flexible substrate can give a certain amount of compliancy to the structure, this technique encounters many difficulties in controlling dimensional stability prior to and during the assembly steps. The protruded pins would cause tremendous handling issues during assembly and induce unwanted bending and shorting after assembly and hence have an adverse effection the assembly process, making this approach a tedious and less than desirable assembly solution from a manufacturing point of view.

In view of the various development stages and limitations in currently available semiconductor chip assemblies, there is a need to design a method that is cost-effective and provides excellent manufacturing platform for a reliable package. Hence, the prior arts do not fulfill all users requests on actual use.

### SUMMARY OF THE INVENTION

An object of the present invention is to solve the above described problems associated with the prior arts, and provide a method of semiconductor chip assembly using a build-up substrate with a metal-based core carrier wherein the build-up layers are deposited on only one side of the metal carrier. The metal-based core carrier provides the supporting panel for assembly there by enhancing the rigidity co-planarity of the substrate, and hence bonding strength between the semiconductor chip and the build-up substrate.

Throughout the specification, the metal-based core carrier maybe referred to as a metal-based carrier for convenience and metal base in some instances when it does not perform the function of a carrier and is sacrificed through etching.

Another object of the present invention is to provide a method of semiconductor chip assembly u sing a build-up substrate with a metal-based core carrier, where the metal is sacrificial and will be removed in the final stage of the assembly so as to shorten the electrical conduction path between the semiconductor chip and the assembled board, and thereby to enhance package electrical characteristics.

Yet another object of the present invention is to provide a method of semiconductor chip assembly using a build-up substrate with a metal-based core carrier with p re-formed terminal. After the metal-based core carrier is removed, the exposed terminal provides solder locking effect between the package and the assembled board to enhance the board level reliability.

Generally speaking, the present invention provides a method of making a semiconductor chip assembly comprising steps of mechanically and electrically attaching a semiconductor chip to a build-up substrate with a metal-based core carrier where terminals for a board assembly is pre-formed in the metal-based core carrier, forming an en capsulant that covers the chip and the build-up substrate, and removing a portion of the metal-based core carrier to expose the pre-formed terminal and the build-up layers.

In accordance with an aspect of the invention, a method of making a semiconductor chip assembly comprises steps of providing a build-up substrate with a metal-based core carrier, where terminals is pre-formed in the metal-based core carrier and multi-layers are formed on only a single side of the metal-based core carrier, the build-up layers have first and second opposing surfaces, the first surface faces a first direction, and the second surface contacts the metal-based core carrier and extends vertically beyond the metal-based core carrier in a first direction; attaching a semiconductor chip to the build-up substrate, wherein the chip has a first and a second opposing surfaces and the first surface of the chip has a conductive pad; electrically interconnecting the conductive pad to the build-up substrate; forming an en capsulant that covers and extends vertically beyond the chip, the build-up substrate in the first direction; and, etching a portion of the metal-based core carrier without etching the build-up substrate to thereby expose the pre-formed terminal that extends vertically beyond the build-up substrate in the second direction.

In another aspect of the present invention, there is provided a method of forming the build-up substrate by sequentially depositing a plurality of conductive layers and insulating layers alternatively on the first surface of the metal-based core carrier such that the build-up substrate extends vertically beyond the supporting metal base in the first direction.

In yet another aspect of the present invention, the method of forming the build-up substrate includes steps of depositing the first dielectric layer substantially on the first surface of the metal-based carrier support, where the first dielectric layer has an opening that exposes a portion of the metal-based core carrier; electroplating only on the exposed portion of the metal-based core carrier to form contacting terminal pads; and forming the first wiring layer onto a first insulating layer by electro-less and electro-pattern plating respectively, where the wiring layers are electrically interconnected by via hole formed in the dielectric layers.

In accordance with one embodiment of the present invention, the method of making a semiconductor chip assembly includes a step of attaching the chip to the build-up substrate with a metal-based core carrier such that the chip extends vertically beyond the build-up substrate and the metal-based core carrier in the first direction.

In accordance with another embodiment of the present invention, the method includes steps of mechanically attaching the chip to the build-up substrate, and forming a connection joint that electrically connects the chip, the build-up substrate, and the metal base.

It is possible that the method of assembly includes a step of forming the connection joint by mechanically fusing the metal bump to the conductive pad on the build-up substrate. For instance, a gold-gold connection joint is formed by applying an ultrasonic power on the chip with a gold bump deposited on the bonding pad of the chip and the gold deposit on the conductive pad of the substrate.

It is also possible that the method of assembly includes forming the connection joint by thermally fusing the metal bump to the conductive pad on the build-up substrate. For example, a gold-tin connection joint is formed by applying heat and pressure on the chip and the metal base with a gold bump deposited on the pad and a solder deposited on the conductive pad.

In accordance with an other aspect of the present invention, the method of assembly includes a step of forming the encapsulant prior to etching the metal base as the encapsulant provides a mechanical support to the build-up substrate after the metal-based core carrier is etched.

In accordance with one embodiment of the present, the method includes a step of etching the metal-based core carrier completely after forming the encapsulant and thereby eliminating all the contact are a between the metal base and the build-up layers.

Alternatively, by etching the metal-based core carrier, a first portion of the metal carrier is removed to reduce the contact area to the first wiring layer without removing a second portion of the metal that contacts the terminal, thereby reducing but not eliminating contact area between the metal base and the build-up substrate.

In yet a further embodiment, the method includes a step of etching a portion of the metal base to electrically isolate the individual circuitry pattern from each other.

The method of the present invention includes a step of forming an insulation base that substantially covers the first wiring layer in the second direction without covering the terminal, and the insulating base extends vertically beyond the chip, the build-up layers, and the encapsulant in the second direction.

An advantage of the present invention is that the semiconductor chip assembly can be manufactured conveniently on a solid supporting panel to improve dimensional stability and handling issues.

Another advantage of the present invention is that the metal-based core carrier provides the critical flatness, hardness and rigidity support during flip chip thermo-compression bonding, there by enhancing the bond strength of the chip to the build-up substrate.

Another advantage of the present invention is that the metal-based core carrier provides the important hardness and high thermal conduction during flip chip thermo-sonic bonding, thereby enhancing the bond strength of the chip to the build-up substrate.

Yet another advantage of the present invention is that the assembly made by this method is characterized by high chip-to-substrate bonding strength. The unique metallurgical gold-gold bonding provides superior bonding strength due to the monolithic structure of the gold material formed by the thermo-sonic bonding between gold stud bond and gold pad. The metal-based core carrier provides high thermal conductivity to facilitate thermo-sonic bonding; and, the interconnection maintains low contact resistance, sustains high current flow, and provides superior high frequency performance (low inductance).

Another advantage of the present invention is that the connection joint can be made from a wide variety of materials and processes, thereby making advantageous use of mature connection joint technologies in a unique and improved manufacturing approach.

Another advantage of the present invention is that as the encapsulant can be provided before the metal-based core carrier is etched and removed, the carrier provides the mechanical support and protection for the chip and the routing line during assembly before the metal base is etched.

Yet another advantage of the present invention is that the metal-based core carrier is a sacrificial metal and is not an integral part of the substrate thereby providing a relatively thin substrate.

Another advantage of the present invention is that the assembly made by this method is characterized by the absence of a conventional core and therefore provides the advantages of better signal integrity.

Another advantage of the present invention is that the assembly made by this method is characterized by the absence of a conventional core and therefore provides the advantages of better mechanical reliability.

Yet another advantage of the present invention is that the assembly made by this method is characterized by the pre-formed metal terminals and therefore provides the advantages of better board level reliability.

Another advantage of the present invention is that as the protruded terminal is pre-formed in the metal-based core carrier, this greatly improves manufacturing handling and yield since there will be no post-assembly solder terminal ball attaching process required.

Another advantage of the present invention is that the assembly can be flexible enough to accommodate various chip level interconnect techniques, such as flip chip, wire bonds or TAB leads without requiring extra tooling and supporting frame.

Still another advantage of the present invention is that the assembly can be manufactured using materials that are compatible with copper chip and lead-free environmental requirements.

These and other objects features and advantages of the invention will be further described and more readily apparent from a review of the detailed description of the preferred embodiments which follows.

### BRIEF DESCRIPTION OF THE DRAWINGS

The present invention will be better understood from the following detailed descriptions of the preferred embodiments according to the present invention, taken in conjunction with the accompanying drawings, in which

FIG. 1 is the cross sectional view of a conventional build-up substrate;

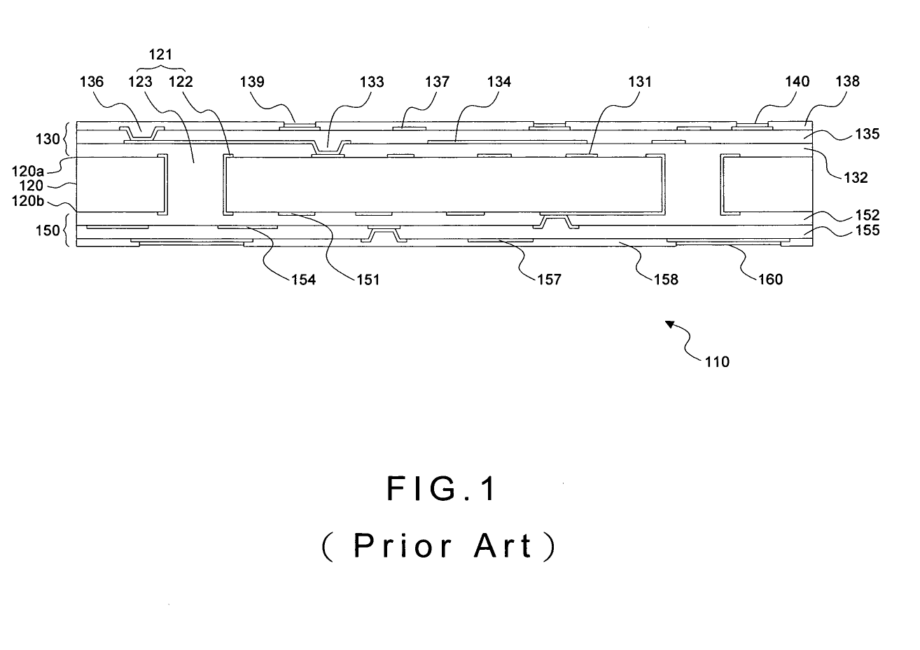

FIG. 2 is the cross sectional view showing the build-up substrate according to the preferred embodiment of the present invention;

FIG. 3 is the cross-sectional view showing the semiconductor device package;

FIG. 4A is the cross sectional view showing gold bumps formed on the surface of the semiconductor chip;

FIG. 4B is the view showing the semiconductor chip mounted onto the build-up substrate;

FIG. 4C is the view showing the thermo-setting resin under-filled between the semiconductor chip and the build-up substrate;

FIG. 4D is the view showing the encapsulant formed on the build-up substrate;

FIG. 4E is the view showing the structure of the assembly after the metal-based core carrier is removed; and

FIG. 5 is the cross sectional view showing the assembly according to another preferred embodiment.

### DESCRIPTION OF THE PREFERRED EMBODIMENT

The following descriptions of the preferred embodiments are provided to understand the features and the structures of the present invention.

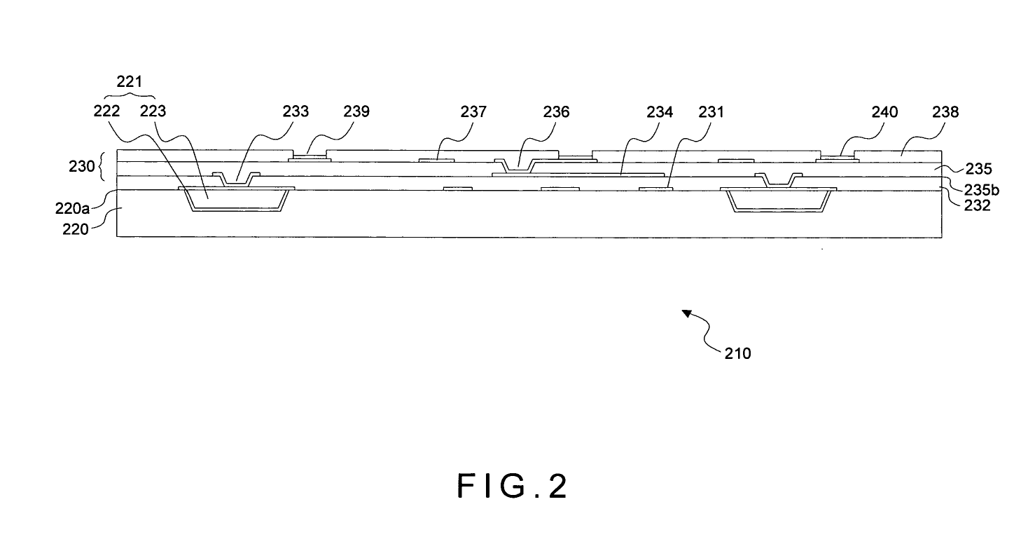

Please refer to FIG. 2, which is a cross sectional view showing a build-up substrate according to a preferred embodiment of the present invention.

As shown in the figure, the present invention is a build-up substrate 210 with a metal-based core carrier 220 where the build-up layers are deposited on the first surface 220a of the metal-based core carrier 220. The metal-based core carrier 220 is typically made of a copper plate or other materials, such as aluminum or metal alloys, that can be chemically etched or mechanically removed.

For ease of reference, throughout the description of the present invention, the metal-based core carrier 220 may be referred to as a metal-based core carrier for convenience or as a metal base in some instances when it does not perform the function of a carrier, and is sacrificed through etching.

As shown in FIG. 2, the metal-based core carrier 220 has a terminal 221 which includes a terminal metal 222 and a conductive filler 223 sequentially deposited into cavities (not shown) formed under the first surface 220a of the metal-based core carrier 220 using a photoresist layer (not shown) as an etching mask. The terminal metal 222 typically is a solder wettable material, such as gold, tin, silver, palladium and alloys. The conductive filler 223 is made of a metal, such as copper, nickel, gold, silver and palladium, or an alloy, such as solder, or a conductive adhesive. The terminal 221 extends from a first surface 220a of the metal-based core carrier 220 into but not through the metal-based core carrier 220. In essence, cavities on the first surface 220a provide a pre-formed shape of the terminals 221 after a plurality of the metal-based core carrier 220 is removed.

A first wiring layer 231 on the first surface 220a comprises an electroplated copper layer over a nickel layer. However, various combinations and different metallic systems can be used for the first wiring layer 231 depending on the required technical application. For convenience of illustration, the nickel and copper layers in the first wiring layer 231 are shown as a single metallic conductive layer. The first wiring layer 231 and the terminal metal 222 may be plated separately or simultaneously formed by an electroplating operation using a photo resist (not shown) as plating masks. These layers are formed additively. A first dielectric layer 232 made of a n epoxy resin is coated on the first surface 220a covering the first wiring layer 231 and the pre-formed terminals 221 in a first direction. A plurality of first level via holes 233 is formed in the first dielectric layer 232, exposing a portion of the first wiring layer 231. A second wiring layer 234 is formed on the first dielectric layer 232, and a portion of the second wiring layer 234 extends into the first level via holes 233 contacting the first wiring layer 231. A second dielectric layer 235 is coated on the first dielectric layer 232, and covers the second wiring layer 234 A plurality of second level via holes 236 is formed in the second dielectric layer bottom 235a exposing the second wiring layer 234. A third wiring layer 237 is formed on the second dielectric layer 235 and a portion of the third wiring layer 237 extends into the second level via holes 236 contacting the second wiring layer 234 in the first direction.

A solder resist layer 238 is coated on the second dielectric layer 235 covering the third wiring layer 237 in the first direction. A plurality of openings 239 are formed in the solder resist layer 238 exposing the third wiring layer 237; and, a plurality of conductive pads 240 are deposited into the openings 239 on the third wiring layer 237.

The metal-based core carrier 220, the pre-formed terminals 221, the first, the second and the third wiring layers 231, 234, 237, the first and the second dielectric layers 232, 235 and a plurality of the conductive pads 240 constitute the build-up substrate with a metal-based core carrier 220.

FIG. 2 depicts the method of providing a three layers build-up substrate with a metal-based core carrier 220. The same method can be used to build different number of layers of the build-up substrate as required according to different applications.

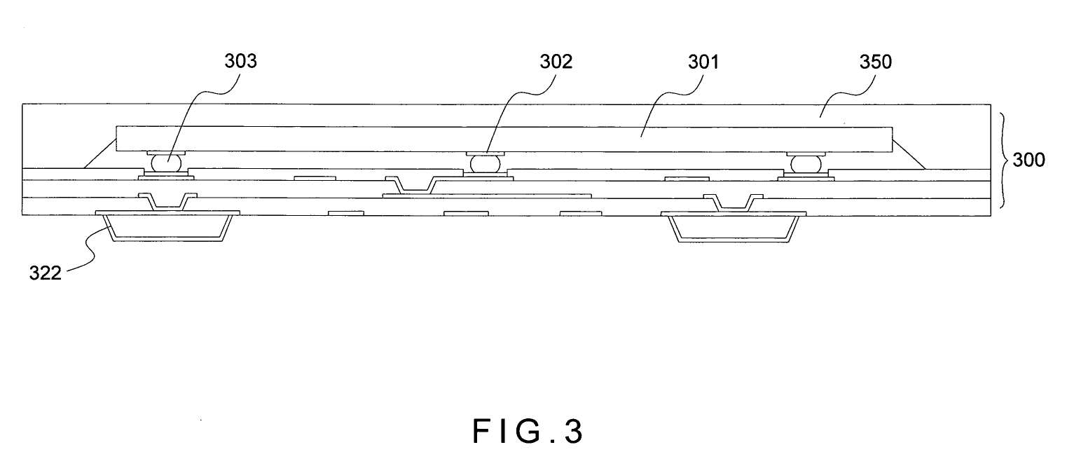

Please refer to FIG. 3, which is a cross-sectional view showing a semiconductor device package. As shown in the figure, a semiconductor device 300 includes a semiconductor chip 301 having electrodes 302 and a plurality of bumps 303, which is flip mounted on conductive pads 340 of build-up layers 330. Terminals 322 are served as interconnects for a next level assembly and are pre-formed in the metal-based core carrier 320; and are exposed after selective portions of a metal base are removed.

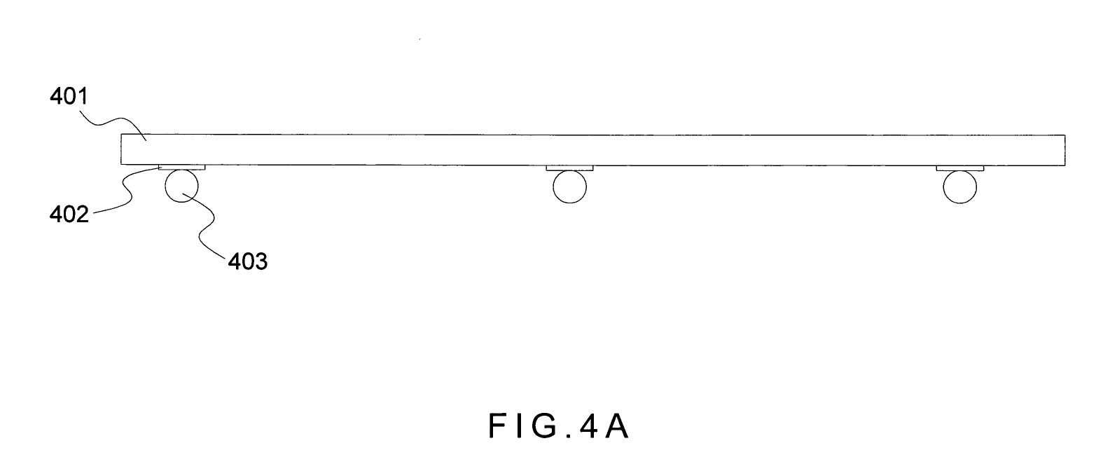

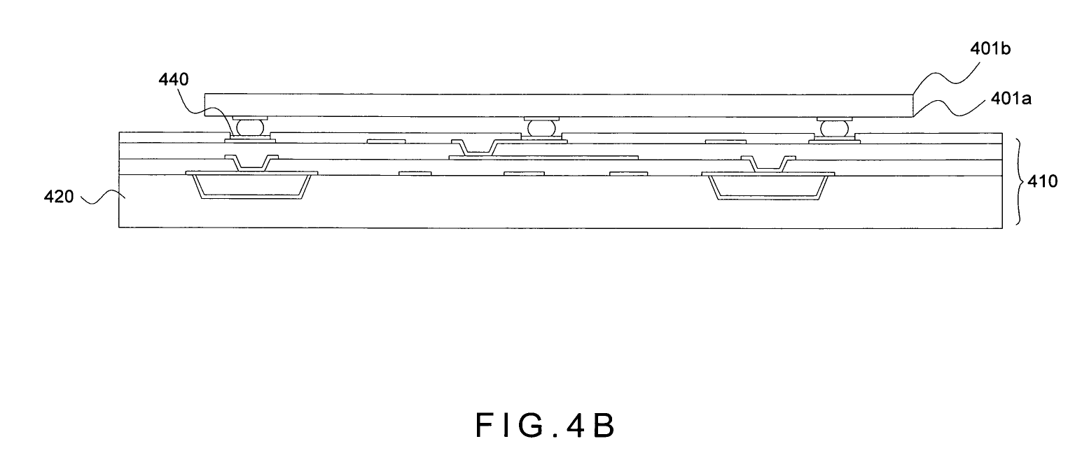

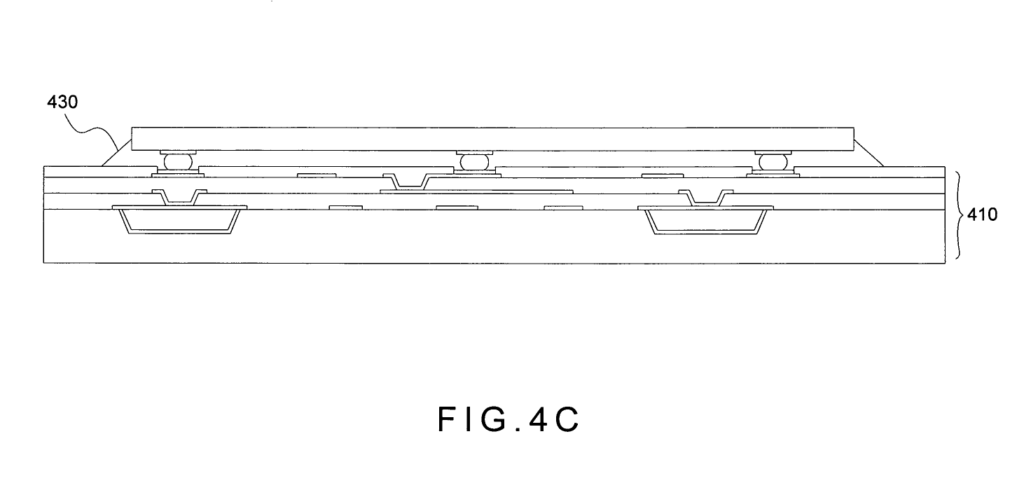

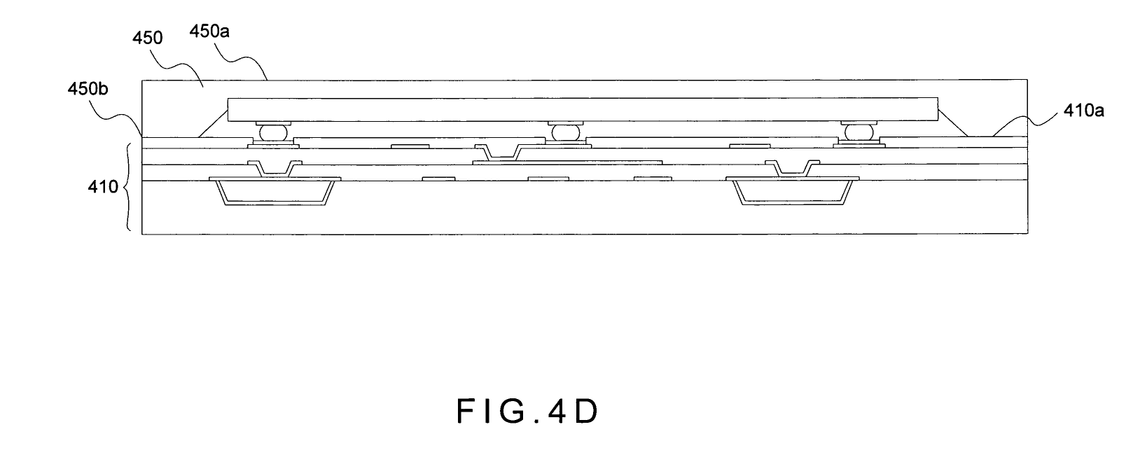

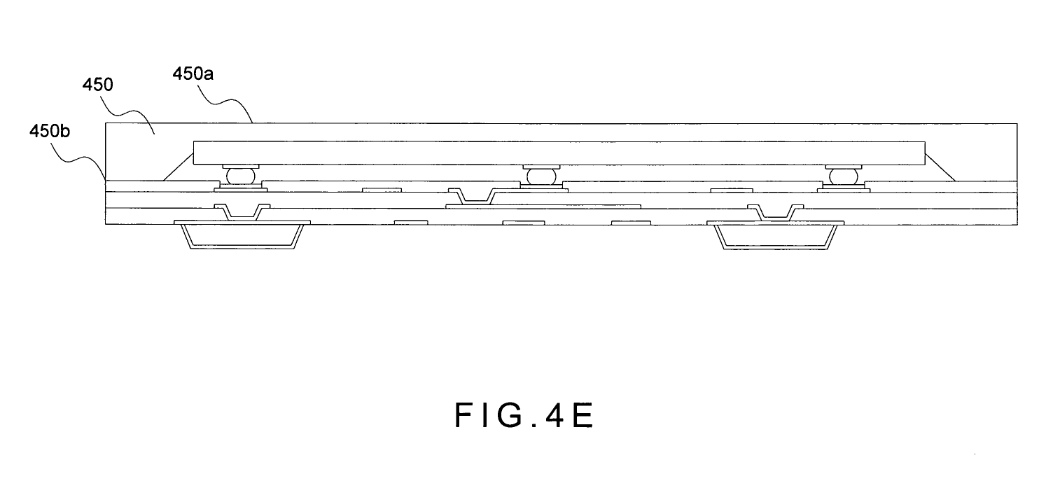

A method for manufacturing the semiconductor device 300 having the fore going structure is explained with reference to FIG. 4A to 4E.

Please refer to FIG. 4A, which is a cross sectional view showing gold bumps formed o n a surface of a semiconductor chip. As shown in the figure, a plurality of gold bumps 403 is formed on each electrode 402 on the surface of a semiconductor chip 401. The gold bumps 403 are formed in a protruding or hemispherical shape by a wire bonding or a metal plating. However, the bumped material is not limited to gold, yet other materials, such as solder, copper or aluminum, etc., are applicable.

Please further refer to FIG. 4B, which is a view showing the semiconductor chip mounted onto a build-up substrate. As shown in the figure, the semiconductor chip 401 is mounted onto a metal-based build-up substrate 410 with a surface 401a of the semiconductor chip 401 having the gold bumps 403 facing downward; and then, heat and pressure is applied to the semiconductor chip 401 so as to forge the gold bumps 403 to conductive pads 440 on the build-up substrate 410. Thus, the gold bumps 403 contact and electrically connect the electrodes 402 to the respective plated conductive pads 440; and all the bonding pads of electrodes 402 are electrically connected and shorted together through a metal-based core carrier 420. In this flip chip arrangement, the surface 401a of the semiconductor chip 401 faces downwardly and contacts build-up layers; another surface 401b of the semiconductor chip 401 faces upwardly away from the build-up substrate 410 and is exposed.

Please further refer to FIG. 4C, which is a view showing a thermo-setting resin under-filled between the semiconductor chip and the build-up substrate. As shown in the figure, a thermo-setting resin 430 is thereafter hardened by heat and serves as an adhesive to fasten the semiconductor chip 401 to the build-up substrate 410. The thermo-setting resin 430 contacts and extends between the surface 401 a of the semiconductor chip 401 and the build-up substrate 410. The thermo-setting resin 430 also contacts an outer edge of the semiconductor chip 401.

Please refer to FIG. 4D, which is a view showing an encapsulant formed on the build-up substrate. As shown in the figure, an encapsulant 450 has opposing surfaces 450a, 450b. One of the opposing surfaces 450a faces upwardly, and the other surface 450b faces downwardly. The encapsulant 450 extends upwardly beyond the semiconductor chip 401, the thermo-setting resin 430, and the build-up substrate 410. More particularly, the encapsulant 450 contacts a surface 410b of the semiconductor chip 401; the thermo-setting resin 430 from the outer edge of the semiconductor chip 401; and a surface 410a of the build-up substrate 410. And the encapsulant 450 covers but is spaced from the metal-based core carrier 420 due to the build-up layers. The encapsulant 450 is a solid ad he rent compressible protective layer that provides environmental protection such as moisture resistance and particle protection for chip as well as mechanical support for the build-up layers after metal base is removed.

The encapsulant 450 can be deposited by using a wide variety of techniques, including printing and transfer molding. For instance, the encapsulant 450 can be printed onto the semiconductor chip 401 with the build-up layers as an epoxy paste and then be cured or hardened to form a solid adherent protective layer. On the other hand, the encapsulant 450 need not necessarily contact the semiconductor chip 401 or the build-up layers. For instance, a glob-top coating can be deposited on the semiconductor chip 401 after attaching the semiconductor chip 401 to the build-up substrate 410, and then the encapsulant can be formed on the glob-top coating. The epoxy paste or molding compounds are well-known in the art.

The encapsulant 450 not only provides major mechanical support for the semiconductor chip 401 and the build-up layers, it also reduces mechanical strain on the build-up layers, which is particularly useful after the metal base is removed. Encapsulant also protects the chip, the build-up layers, and the terminal from mechanical damage during the wet chemical etching and subsequent cleaning steps (such as rinsing in a distilled water or an air blowing). For instance, the encapsulant absorbs physical force of wet chemical etching and cleaning steps that might otherwise separate the semiconductor chip and the build-up layers. Thus, the encapsulant improves a structural integrity and allows wet chemical etching and subsequent cleaning steps to be applied more vigorously, thereby improving manufacturing throughput.

Please refer to FIG. 4E, which is a view showing a structure of an assembly after the metal-based core carrier is removed. As shown in the figure, the metal-based core carrier 420 is removed by applying blanket of back-side wet chemical etching. For instance, a bottom spray nozzle can spray a wet chemical etching on the metal-based core carrier 420 while a top spray nozzle is deactivated, or the whole structure can be dipped in the wet chemical etching since encapsulant provides front-side protection. The wet chemical etching is highly selective of copper with respect to nickel, gold, resin, solder mask and molding compound; and therefore, highly selective of metal base with respect to a nickel layer of a first wiring layer and gold of a bumped terminal metal, resin and encapsulant. Furthermore, the nickel layer of the first wiring layer and gold of the bumped terminal metal protects underlying copper layer of the first wiring layer and bumped terminal from the wet chemical etching. Therefore, no appreciable amount of first wiring layer, bumped terminal, resin or encapsulant is removed. Furthermore, chip, bump, and higher wiring layers are not exposed to the wet chemical etching.

Since the wet chemical etching mainly removes the metal base, the wet chemical etching eliminates contact area between metal-based carrier and first wiring layer, eliminates contact area between metal-base carrier and first dielectric layer, and eliminates contact between metal-base carrier and pre-formed terminal. The wet chemical etching exposes first wiring layer, first dielectric layer and pre-formed terminal, without exposing encapsulant and semiconductor chip.

A suitable wet chemical etching can be provided by a solution containing alkaline ammonia. The optimal etching time for removing the metal base without excessively exposing wiring circuitry and pre-formed terminal to the wet chemical etching can be established through trial and error.

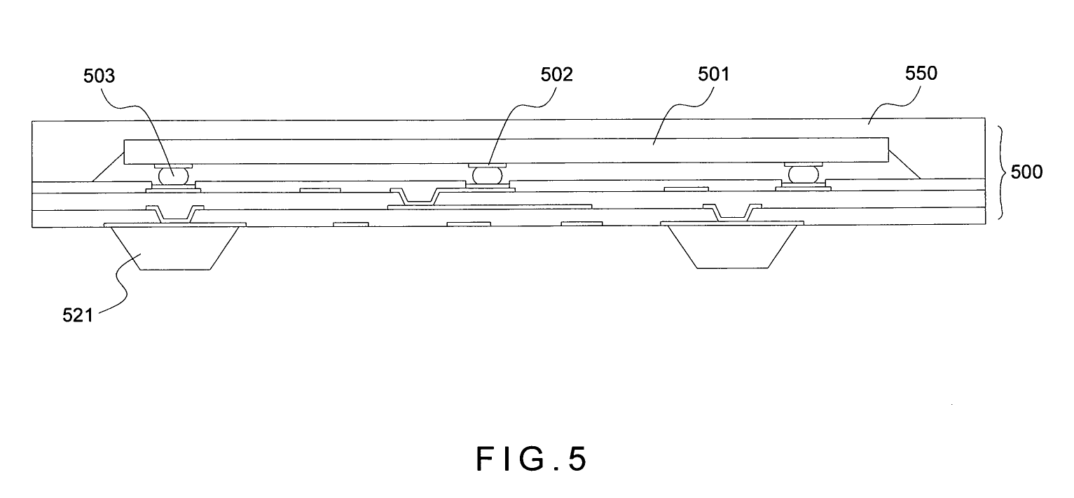

Please refer to FIG. 5, which is a cross sectional view showing an assembly according to another preferred embodiment. As shown in the figure, a method of making a semiconductor chip assembly 500 includes step of mechanically attaching a semiconductor chip 501 to a multi-layer build-up substrate, wherein the semiconductor chip 501 includes electrodes 502 and a plurality of gold bumps 503 formed on the electrodes 502; and an encapsulant 550 covers the semiconductor chip 501 and the build-up substrate. The metal base (not shown) is then selectively etched to form the metal pillar terminals 521.

The metal pillar terminals 521 are formed only after the encapsulant 550 covers the semiconductor chip 501 to provide a mechanical support. This approach provides an assembly-friendly process as having the metal pillar terminals 521 formed prior to chip assembly; and would require special handling carriers to avoid damaging the metal pillar terminals 521 as the assembly is being processed. A soldering material (not shown) can be deposited on the metal pillar terminals 521 to form a solder terminal if needed.

The metal pillar terminals 521 can be formed by selective etching of metal base (not shown) thereby forming an array of protruded portion that extends vertically beyond the build-up layer in the second direction. The selectivity of etching is dictated by depositing a photo-resist mask (not shown) or a metal mask (not shown) on the second surface of the metal base, thereby the portion of the metal base underneath the mask is remained after etching.

The semiconductor chip assemblies described above are merely exemplary. Numerous other embodiments are contemplated. For instance, the flip chip arrangement described above can be converted to a wire bonding assembly format when the chip is not inverted. Likewise, the pre-formed terminal can have various shapes such as a tapered pillar terminal, a flat terminal, or a curved and bumped shapes depending on design and reliability considerations.

The conductive filler does not necessarily fill the cavity completely. Likewise, the metal base does not necessarily be removed completely during base etching. For instance, a portion of the metal base that is spaced from the terminal can remain intact and provide a heat sink function.

The wiring layers are made from various conductive metals including copper, gold, nickel, silver, palladium, tin, combinations there of, and alloys thereof. The preferred composition of the wiring layers depends on the process compatibility as well as design and reliability factors, and the wiring layers can fan-in as well as fan-out. Those skilled in the art will understand that in the context of a semiconductor chip assembly.

The first wiring layer is formed on the metal-base carrier by numerous deposition techniques, including electroplating or electro-less plating. As an example, the first wiring layer includes a non-copper layer electroplated on a copper base followed by a copper layer electroplated on the non-copper layer. Suitable non-copper layers for the electroplating process include nickel, gold, palladium and silver. After the encapsulant is formed, a wet chemical etching is then applied; and the wet chemical etching is highly selective of copper with respect to the non-copper layer to etch the copper base and expose the first wiring layer without removing the copper or non-copper layers. The non-copper layer provides an etching stop that prevents the wet chemical etching from removing the copper layer. Furthermore, it is understood that in the context of the present invention, the first wiring layer and the metal base are different metallic materials even if a multi-layer routing line includes a single layer that is similar to the metal base such as the example described above. Likewise, the terminal conductors can be formed in the same manner and simultaneously with the first wiring layer.

A soldering material or a solder ball can be deposited on the terminal by printing or placement techniques if required for the next level assembly. However, the next level assembly may not require that the semiconductor chip assembly contains solder.

It is understood that, in the context of the present invention, any chip embedded in the encapsulant is electrically connected to the terminals by an electrically conductive path that includes the build-up layers means that the build-up layers is in an electrically conductive path between the respective terminal and any chip embedded in the encapsulant.

This is true regardless of whether a single chip is embedded in the encapsulant or multiple chips are embedded in the encapsulant. This is also true regardless of whether the electrically conductive path includes or requires a passive component such as a capacitor or a resistor. This is also true regardless of whether multiple chips are electrically connected to the build-up layers by multiple connection joints. This is also true regardless of whether multiple chips are electrically connected to the terminal by different electrically conductive paths as long as each of the electrically conductive paths includes the build-up layers.

The “first” and “second” vertical directions do not depend on the orientation of the assembly, as will be readily apparent to those skilled in the art. For instance, the encapsulant extends vertically beyond the build-up layers in the “first direction”, the terminal extends vertically beyond the build-up layers in the “second” direction, regardless of whether the assembly is inverted and/or mounted on a printed circuit board. Likewise, the wiring layers in the build-up layers extends “laterally” and the via holes in the build-up layers extends “vertically” regardless of whether the assembly is inverted, rotated or slated. Thus, the “first” and “second” directions are opposite to one another and orthogonal to the “lateral” direction. Moreover, the chip is shown above the build-up layers and the terminal. The encapsulant is shown above the chip, the build-up layers and the terminal with a single orientation throughout the drawings for ease of comparison between the figures, although the assembly and its components may be inverted at various manufacturing stages.

Advantageously, the semiconductor chip assembly method of the present invention is reliable and inexpensive especially for high performance semiconductor chip and modules. The metal base provides dimensional stability and rigidity support, and ensures a reliable bonding between the chip and the build-up layers during chip attachment stage. The encapsulant takes over the role and provides mechanical support and protection for the chip and build-up layers after the metal base is etched and removed. The build-up layers provide sophisticated electrical routing capability, and ensure known dielectric barrier for the circuitry patterns such that the electrical characteristics can be precisely controlled.

The process is highly versatile and permits a wide variety of mature connection joint technologies to be used in a unique and improved manner. As a result, the assembly of the present invention significantly enhances throughput, yield and performance characteristics compared to conventional packaging techniques. Moreover, the assembly of the present invention is well-suited for use with materials compatible with copper chip requirements.

Various changes and modifications to the preferred embodiments described herein will be apparent to those skilled in the art. For instance, the materials, dimensions and shapes described above are merely exemplary. Such changes and modifications may be made without departing from the spirit and scope of the present invention as defined in the appended claims.

What is claimed is:

1. A method of obtaining a semiconductor chip assembly, comprising steps of:
providing a multi-layer build-up substrate,
wherein said multi-layer build-up substrate comprises build-up layers and a metal-based core carrier, said build-up layers has a first and a second opposing surfaces, said first surface faces a first direction, said second surface contacts said metal-based core carrier and extends vertically beyond said metal-based core carrier in said first direction, and said build-up layers are electrically connected through said metal-based core carrier;
mechanically attaching a semiconductor chip to said multi-layer build-up substrate,
wherein said chip has a first and a second opposing surfaces, and said first surface of said chip has an electrode;
forming a connection joint that electrically connects said build-up substrate and said electrodes of said chip;
forming an encapsulant to cover said chip and said build-up substrate,
wherein said encapsulant has a first surface that faces in a first direction and a second surface that faces in a second direction opposite to said first direction, said encapsulant extends vertically beyond said chip, said build-up layers and said metal-based core carrier in said first direction; and
etching said metal-based core carrier, and thereby forming said semiconductor chip assembly.

2. The method according to claim 1,
wherein providing said build-up substrate comprises steps of:
forming a plurality of cavities on said metal-based core carrier;
depositing terminal conductors in said cavities; and
sequentially depositing wiring layers on said metal-based core carrier.

3. The method according to claim 2, wherein forming a plurality of cavities comprises steps of:
forming a plating mask on said metal-based core carrier,
wherein said plating mask has an opening that exposes a portion of said metal-based core carrier; and
etching said exposed portion of said metal-based core carrier through said opening in said plating mask without etching through said metal-based core carrier.

4. The method according to claim 2 wherein depositing terminal conductors comprises steps of:
forming a plating mask on said metal-based core carrier,
wherein said plating mask has an opening that exposes a portion of said cavity; and
forming said terminal conductors in said cavity by sequentially depositing said terminal conductors and conductive fillers through said opening of said plating mask and covering said terminal conductors and conductive fillers by said metal-based core carrier in said second direction.

5. The method according to claim 2, wherein sequentially depositing wiring layers on said metal-based core carrier has a process of depositing at least two wiring layers as an upper wiring layer and an underlying layer; and one dielectric layer in between.

6. The method according to claim 5, wherein sequentially depositing wiring layers has a process of connecting said upper wiring layer to said underlying wiring layer through at least one conductive via in said dielectric layer.

7. The method according to claim 1, wherein forming said build-up substrate comprises steps of:
depositing terminal conductors on said metal-based core carrier to form a terminal without forming a plurality of cavities on said metal-based core carrier; and
sequentially depositing wiring layers on said metal-based core carrier.

8. The method according to claim 1, wherein said method further comprises a step of:
attaching and interconnecting said semiconductor chip to said build-up substrate prior to etching said metal-based core carrier.

9. The method according to claim 1, wherein said forming of said encapsulant is carried out prior to etching said metal-based core carrier.

10. The method according to claim 1, wherein etching said metal-based core carrier has a process of exposing said first wiring layer, a first dielectric layer, and said terminal conductor without exposing said encapsulant in said second direction.

11. The method according to claim 1, wherein etching said metal-based core carrier electrically isolates a circuitry pattern from other circuitry patterns formed in said build-up layers.
